(19) United States
(12) Patent Application Publication
(10) Pub. No.: US 2025/0004043 A1
(43) Pub. Date: Jan. 2, 2025

(54) WAFER INSPECTION APPARATUS

(71) Applicant: Hitachi High-Tech Corporation, Minato-ku, Tokyo (JP)

(72) Inventors: Yoshihiro SATOU, Tokyo (JP); Toshio MASUDA, Tokyo (JP); Akio YAZAKI, Tokyo (JP); Toshinori KOBAYASHI, Tokyo (JP); Yuichirou IIJIMA, Tokyo (JP); Kenshiro OHTSUBO, Tokyo (JP); Kei SHIBAYAMA, Tokyo (JP); Osamu YOSHIMURA, Tsuchiura-shi, Ibaraki (JP)

(73) Assignee: Hitachi High-Tech Corporation, Minato-ku, Tokyo (JP)

(21) Appl. No.: 18/688,961

(22) PCT Filed: Sep. 8, 2021
(86) PCT No.: PCT/JP2021/032922

§ 371 Date: Mar. 4, 2024

(51) Int. Cl. G01R 31/28

(52) U.S. Cl. CPC G01R 31/2893

(57) ABSTRACT

A purpose of the present invention is to provide a wafer inspection apparatus wherein a solid contact area with the wafer is reduced, and the likelihood of dust emission due to abrasion is reduced. A wafer inspection device 10 comprises a turntable 200 having an annular wafer support part 202, and a clamping mechanism 206 including a holding claw 219 for clamping the wafer, wherein the wafer support part 202 has a contact portion 202a for contacting a lower surface of the wafer and a non-contact portion 202b that does not contact the lower surface of the wafer, the contact portion 202a and the non-contact portion 202b are alternately arranged in the circumferential direction of the turntable 200 so as to face the outer circumferential portion of the lower surface of the wafer 205, and are provided such that the length in the circumferential direction of the contact portion 202a is shorter than the length in the circumferential direction of the non-contact portion 202b.

### TECHNICAL FIELD

The present invention relates to an inspection apparatus for inspecting a wafer.

### BACKGROUND ART

In a semiconductor manufacturing process, the presence of foreign matters on a substrate such as a semiconductor wafer causes defects such as a wiring insulation defect or short circuit. These foreign matters are mixed in various states, such as foreign matters generated from movable portions such as a conveyance device, foreign matters generated from a human body, foreign matters generated by a reaction in a processing apparatus with a process gas, and foreign matters mixed in chemicals or materials. The same applies to a process of manufacturing a magnetic disk or a liquid crystal display element, and adhesion of generated foreign matters to a substrate (magnetic disk or liquid crystal display element) causes a defect.

Therefore, by detecting and managing the foreign matters on a wafer surface using a surface inspection apparatus, a dust generation status of each manufacturing apparatus, cleanliness of each process, and the like are monitored and controlled to improve quality, yields, and the like of products. In the foreign matter inspection method, the wafer surface is irradiated with light such as a laser light, and scattered light from the foreign matter is detected to inspect a size, an adhering position, and the like of the foreign matter to be obtained as unique information of each wafer. A method of holding the wafer is roughly classified into a back surface adsorption type and a back surface non-contact type. In the back surface adsorption type, an air adsorption port is provided in a flat table to adsorb a back surface of the wafer. In the back surface non-contact type, an end of the vicinity of the outer periphery of the wafer is held. The back surface adsorption type is used for both a wafer on which a pattern is formed and a bare wafer before forming the pattern thereon. In contrast, the back surface non-contact type is used for such a bare wafer. An X-Y type table is used for foreign matter inspection for the pattern wafer, and a turntable type is used for high speed inspection for the bare wafer. In particular, the back surface non-contact type surface inspection apparatus is used for an outgoing inspection of wafers in wafer manufacturers, an incoming inspection of wafers and management of a manufacturing apparatus in device manufacturers, and the like. Therefore, a stable inspection method is required capable of not only suppressing adhesion of foreign matters but also preventing fluctuations such as temporal changes in a status of foreign matter adhesion. It is also required to reduce metallic contamination on front and back surfaces and an end of the wafer. Prior art related to such a method mainly includes Patent Literature 1.

Patent Literature 1 discloses a wafer turntable including a mechanism for holding an outer peripheral end of a wafer by a vertical rotating claw, and a mechanism for correcting wafer self-weight sinking by blowing air from a center of the turntable onto a wafer back surface so as to be discharged below the outer peripheral portion.

### CITATION LIST

### Patent Literature

PTL 1: US2001/0013684

### SUMMARY OF INVENTION

### Technical Problem

Patent Literature 1 discloses a back surface non-contact type inspection apparatus for bare wafers, in which the wafer is supported with an annular wafer support member having a sloping cross-sectional shape for supporting its own weight provided on a wafer chuck and the above-described vertical rotating claw for supporting the wafer from above. In this case, the wafer support member has a shape for supporting the wafer edge over the entire perimeter thereof, i.e., 360-degree perimeter. In the back surface non-contact type, as a region in contact with the wafer increases, there is a high possibility of generation/adhesion of foreign matters or transfer/increase of metallic contamination due to the contact, which may cause fluctuations in the amount of adhered foreign matters.

The object of the present invention is to provide a wafer inspection apparatus capable of reducing the possibility of generation/adhesion of foreign matters or transfer/increase of metallic contamination due to the contact with the wafer.

### Solution to Problem

In order to achieve the above-described object, a wafer inspection apparatus according to the present invention is a wafer inspection apparatus including a turntable including an annular wafer support unit and a clamping mechanism including a holding claw for clamping a wafer.

The wafer support unit includes a contact portion that is in contact with a lower surface of the wafer, and a non-contact portion that is not in contact with the lower surface of the wafer.

The contact portion and the non-contact portion are alternately arranged in the circumferential direction of the turntable so as to face the outer peripheral portion of the lower surface of the wafer, and are provided such that the length in the circumferential direction of the contact portion is shorter than the length in the circumferential direction of the non-contact portion.

### Advantageous Effects of Invention

The contact region between the wafer and the turntable, which is a factor in the generation and adhesion of foreign matters, can be reduced, thereby reducing the generation/adhesion of foreign matters or transfer of metallic contamination due to the contact. Consequently, it is possible to provide a highly reliable wafer inspection apparatus against foreign matters and metallic contamination.

Problems, configurations, and advantageous effects other than those described above will be clarified by the following description of embodiments.

### BRIEF DESCRIPTION OF DRAWINGS

FIG. 1 is a schematic diagram illustrating a schematic of a system of a wafer inspection apparatus according to the present invention.

FIG. 2A is a perspective diagram illustrating a turntable according to a first embodiment of the present invention.

FIG. 2B is an enlarged diagram illustrating a center portion of a cross-sectional surface taken along the line A-A of FIG. 2A in an enlarged manner.

FIG. 2C is an enlarged view of a vicinity of the wafer clamping mechanism of a cross-sectional surface taken along the line A-A of FIG. 2A.

FIG. 3A is a diagram illustrating a turntable according to the present invention on which a wafer is mounted, as observed from a +Z direction.

FIG. 3B is a diagram illustrating a positional relationship between a wafer outer peripheral portion and a ring-shaped wafer support unit, observed from a surface taken along the line B-B of the turntable in FIG. 2A.

FIG. 3C is a simplified diagram illustrating a cross-sectional surface taken along the line C-C of FIG. 2A.

FIG. 3D is a schematic diagram illustrating a behavior of an airflow of a vicinity of the outer periphery of the turntable when the turntable according to the present invention, on which the wafer is mounted, rotates.

FIG. 4A is a schematic diagram illustrating a behavior of an airflow in a vicinity of the outer periphery of the turntable when the turntable according to the present invention, on which the wafer is mounted, rotates.

FIG. 4B is a graphic chart normalizing, when a gap between the wafer and the turntable is changed, an amount of air flowing into the gap from an outside.

FIG. 4C is a graphic chart of a pressure loss according to, when the gap between the wafer and the turntable is changed, the gap amount.

FIG. 5A is a diagram according to a second embodiment of the present invention, which is a perspective diagram schematically illustrating, when a normal line of a stepped surface of a wafer support unit faces an outer peripheral side of the turntable, a flow line of an airflow in the vicinity of the outer periphery of the turntable which flows toward the stepped surface.

FIG. 5B is a diagram according to the second embodiment of the present invention, which is an X-Y plane diagram schematically illustrating, when the normal line of the stepped surface of the wafer support unit faces the outer peripheral side of the turntable, pressure distribution generated on the stepped surface.

FIG. 5C is a diagram according to the comparative example with respect to the second embodiment of the present invention, which is a perspective diagram schematically illustrating, when a normal line of a stepped surface of a wafer support unit is in a tangential direction, a flow line of an airflow in the vicinity of the outer periphery of the turntable which flows toward the stepped surface.

FIG. 5D is a diagram according to the comparative example with respect to the second embodiment of the present invention, which is an X-Y plane diagram schematically illustrating, when a normal line of a stepped surface of a wafer support unit is in a tangential direction, pressure distribution generated on the stepped surface.

### DESCRIPTION OF EMBODIMENTS

Hereinafter, embodiments according to the present invention will be described.

### Embodiment 1

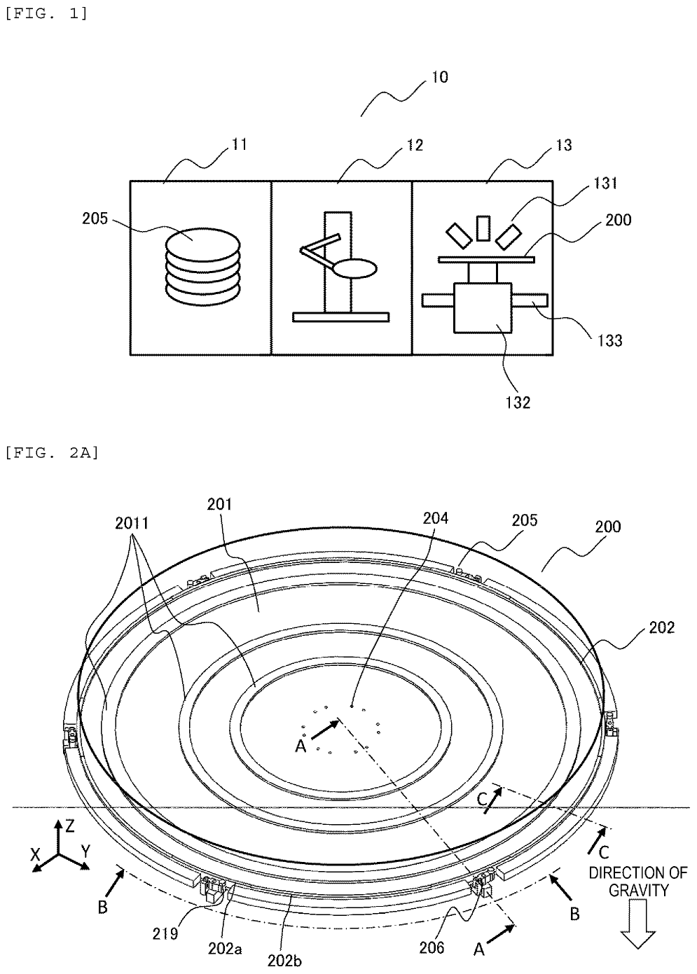

A first embodiment of the present invention will now be described with reference to FIGS. 1 to 4C. A direction along a wafer surface is referred to as an XY or horizontal direction, and a direction perpendicular thereto is referred to as a Z direction or perpendicular direction.

The feature of the present embodiment is that a contact region of a turntable with a wafer is a peripheral region of a holding claw on a wafer outer periphery, and a gap with the wafer is provided on the rest thereof, and the gap in the Z direction is 0.4 mm or less, and more preferably 0.3 mm or less.

FIG. 1 is a schematic diagram illustrating a schematic of a system of a wafer inspection apparatus according to the present invention. As illustrated in FIG. 1, a wafer inspection apparatus 10 is mainly configured with a unit (a wafer introduction unit, a cassette) 11 configured to introduce a wafer 205 from an outside, a mechanism unit (a wafer conveyance mechanism unit) 12 configured to convey the wafer 205, an inspection chamber 13 and a control unit which is not illustrated. The wafer inspection apparatus 10 is installed in a space where cleanliness is maintained so as not to allow foreign matter to adhere to the wafer 205.

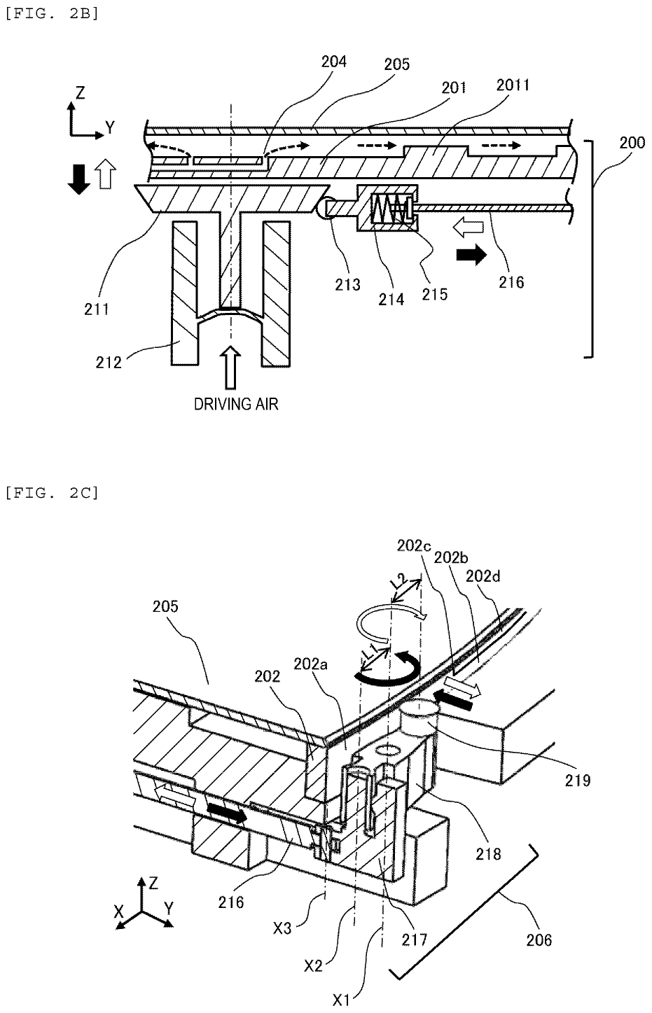

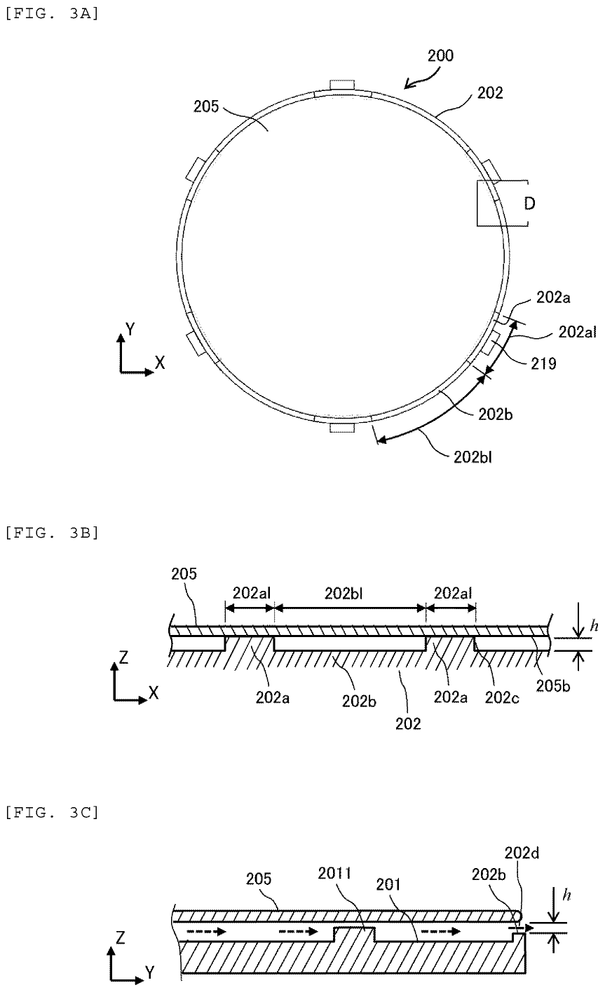

An overview of an operation of the wafer inspection apparatus 10 will now be described with reference to FIG. 2A together with FIG. 1. FIG. 2A is a perspective diagram illustrating a turntable according to a first embodiment of the present invention.

The wafer 205 in a state of being housed in the cassette which is not illustrated is loaded into the wafer introduction unit 11. Thereafter, the wafer 205 is removed from the cassette by the wafer conveyance mechanism unit 12 and is moved to the inspection chamber 13. The wafer 205 moved to the inspection chamber 13 by the conveyance mechanism 12 is placed on a ring-shaped wafer support unit 202 disposed on a turntable 200 which is a mounting unit. Thus, the wafer 205 is disposed on a position opposite to the direction of gravity with respect to the turntable 200. Thereafter, the wafer 205 is held by a clamping mechanism 206 built in the turntable 200 so as not to fall out of the turntable 200. Moreover, clean air (back surface air) is discharged from an air inlet 204 of a vicinity of the center of the turntable to a back surface of the wafer 205, which has sunk under its own weight due to gravity, to generate pressure and correct the self-weight sinking of the wafer 205.

The backside air flows through a gap between the turntable 200 and the wafer 205 toward the outer periphery. At this time, concentrically arranged annular ribs 2011 optimize pressure distribution of the back surface of the wafer so that the wafer 205 is flat.

In the present embodiment, a notch-shaped non-contact region 202b is provided on the wafer support unit 202 described later, and the non-contact region 202b is also used as an air outlet. Alternatively, a dedicated air outlet may be provided in a turntable base 201.

The turntable 200 securing the flatness and holding the wafer 205 as described above is rotationally driven by a motor 132 and is moved in the vertical direction with respect to a rotation axis of the motor 132 by a linear motion moving unit 133, to measure foreign matter on the wafer 205 by an optical measurement unit 131, which is fixed in position. With these movements, a size, a position, and the like of the foreign matter of the entire surface of the wafer 205 are mapped by the control unit to be recorded as foreign matter data of the wafer 205.

The wafer 205 for which the measurement is completed is released from its hold from the clamping mechanism 206, and then is transported again from the turntable 200 by the wafer conveyance mechanism unit 12 and returned to the wafer introduction unit 11 of the wafer. The above process is repeated to inspect all the wafers in the cassette for foreign matters. The wafer introduction unit 11 may also be referred to as the cassette.

Next, a configuration and an operation of the clamping mechanism 206 with respect to the turntable 200 of the wafer 205 will be described.

The configuration of the clamping mechanism 206 will now be described with reference to FIGS. 2B and 2C. FIG. 2B is an enlarged diagram illustrating a center portion of a cross-sectional surface taken along the line A-A of FIG. 2A in an enlarged manner. FIG. 2C is an enlarged view of a vicinity of the wafer clamping mechanism of a cross-sectional surface taken along the line A-A of FIG. 2A.

Directions of the black and white arrows illustrated in FIGS. 2B and C respectively indicate moving directions of the components. The white arrow indicates the moving direction when not clamping the wafer 205, and the black arrow indicates the moving direction when clamping the wafer 205. A configuration and a function of each component will be described hereafter.

The clamping mechanism 206 is built in the turntable 200 on which the wafer 205 is mounted and rotated, and is configured with: an air cylinder 212; a cam 211 attached to the air cylinder 212; a bearing 213 configured to be in contact with the cam 211 and convert a movement of the cam 211 in the vertical direction (Z direction) into the radial direction (XY direction); a bearing holding unit 214 configured to hold the bearing 213; a rod 216 configured to be movable relative to the bearing holding component 214 in the radial direction; a compression spring 215 configured to support the bearing holding unit 214 and the rod 216 in the radial direction; a link 217 configured to allow displacement in the circumferential direction; a holding member 218 configured to rotate and hold a holding claw 219; and the holding claw 219 in contact with the wafer 205.

The air cylinder 212 is mounted on a center portion of the turntable base 201 which is a base of the turntable 200, and moves in the vertical direction (up-and-down direction). As a whole, when the air cylinder 212 operates and the cam 211 moves upward, the holding claw 219 operates so as to be away from the wafer 205 in the radial direction, as indicated by the white arrow in FIG. 2B.

Between the rod 216 and the link 217 and between the link 217 and the holding member 218, each component is supported capable of relatively displacement around rotation axes X1, X2, and X3 illustrated by the dash-dot line in FIG. 2C. The rotational axis direction of each component is an out-of-plane direction of the wafer, and the moving direction of the holding claw 219 is an in-plane direction with respect to the surface of the wafer 205. The mechanisms except for the air cylinder 212 and the cam 211, i.e., the bearing 213, the bearing holding unit 214, the rod 216, the compression spring 215, the link 217, the holding member 218, and the holding claw 219 are symmetrically disposed with respect to the central axis of the turntable 200. The number thereof to be disposed is determined in consideration of a generated holding force and a required holding force of each mechanism.

The back surface air is discharged from the air inlet 204 to the back surface of the wafer, and the back surface air flows through the gap between the turntable base 201 and the wafer 205 toward the outer periphery. This gap is narrow at a portion of the annular rib 2011, and a flow rate of the back surface air toward the turntable outer periphery is adjusted. Consequently, the pressure distribution due to the back surface air on the back surface of the wafer is optimized, and thereby the flatness of the wafer 205 is ensured. Moreover, the wafer inspection apparatus 10 is configured to prevent foreign matter from adhering to the back surface of the wafer by supplying, as a back surface air, clean air containing no foreign matter passing through a clean filter.

An operation of the clamping mechanism 206 will be described below. After the wafer 205 is introduced into the inspection chamber 13 by the wafer conveyance mechanism unit 12, as illustrated in FIG. 2B, driving air is supplied to the air cylinder 212, the cam 211 moves upward, and the rod 216 moves to the inner periphery side. Since the link 217 and the holding claw 219 are attached, in a symmetric position centered on the rotation axis X1, to the holding member 218 holding the holding claw 219, during this time, when the link 217 is displaced to the inner periphery side following the movement of the rod 216 in the direction indicated by the white arrow in FIGS. 2B and 2C, the holding claw 219 is displaced in the outer peripheral side. Consequently, since the position of the holding claw 219 is moved to the outside of the outer peripheral end (outer peripheral edge) of the wafer 205, the turntable 200 is ready to receive the wafer 205. Thereafter, the wafer conveyance mechanism unit 12 places the wafer 205 on the ring-shaped wafer support unit 202 disposed on the turntable 200.

The wafer support unit 202 holds an outer peripheral portion of a surface (lower end surface) facing the turntable 200 of the wafer 205 in the vertical direction. The wafer support unit 202 includes a contact portion 202a holding the wafer 205 in the vicinity of the holding claw 219 and a non-contact portion 202b having a stepped portion 202c between the contact portion 202a and the non-contact portion. The non-contact portion 202b includes a gap portion 202d between the wafer 205 and the non-contact portion.

After the wafer conveyance mechanism unit 12 retracts, in the clamping mechanism 206, the driving air supply to the air cylinder 212 is stopped, as illustrated in FIG. 2B, and the cam 211 moves downward and the rod 216 moves to the outer peripheral side, as indicated by the black arrow in FIG. 2B. When the rod 216 moves to the outer peripheral side, the holding unit 218 horizontally rotates, and the holding claw 219 abuts on the outer peripheral end of the wafer 205 to generate the holding force. During this time, the bearing mount unit 214, the rod 216, and the compression spring 215 connecting these bearing mount unit and the rod integrally moves to the outer peripheral side in the direction indicated by the black arrow in FIGS. 2B and 2C until the holding claw 219 abuts on the outer peripheral end of the wafer 205. Thereafter, the rod 216 stops moving, but the bearing mount unit 214 continues to move to the outer peripheral portion until movement of the cam 211 is completed. At this time, the compression spring 215 contracts as the relative distance between the bearing mount unit 214 and the rod 216 is reduced. Consequently, the compression spring 215 generates an axial force due to a reaction force, and this force is transmitted to the holding claw 219. Consequently, the spring force of the compression spring 215 becomes the holding force of the wafer 205 in the in-plane direction of the holding claw 219. The spring force of the compression spring 215 is a ratio of a distance L1 from a rotation center (supporting point) X1 of the holding member 218 of the holding claw 219 to a joining shaft (force point) X2 of the link 217 and a distance L2 from the rotation center X1 of the holding claw 219 (action point).

The holding claw 219 has a cylindrical shape and is removable, so that when the holding claw 219 is worn out, it can be reused by being removed therefrom and changing a fitting angle of the wafer 205 in the in-plane direction with the holding unit 218 and using a new surface as the abutting surface, thereby achieving enhancement of longevity. If the fitting shape between the holding claw 219 and the holding member 218 is a cylindrical shape, the fitting angle can be freely set, thereby achieving further enhancement of longevity. Of course, there is also an advantage which can ensuring the holding reliability of the wafer 205 in the circumferential direction by using a fitting shape other than the cylindrical shape, e.g., a rectangular fitting shape, to prevent the holding claw 219 from rotating at a fitting portion with the holding member 218. These conditions may be determined in consideration of a fitting strength between the holding claw 219 and the holding unit 218.

Subsequently, the holding force of the clamping mechanism 206 will be described. Functions required for holding the wafer 205 by the clamping mechanism 206 are mainly an alignment function in a state of mounting the wafer 205, a slip prevention function in a rotation start-up state, and a function against a centrifugal force caused by an eccentricity of the wafer 205 in a steady rotating state. The alignment function in the state of mounting the wafer 205 is covered by a static holding force. This holding force is generated by the compression spring 215 of the clamping mechanism 206. Regarding the slip prevention function and the centrifugal force of the wafer, since the centrifugal force generated by each component of the clamping mechanism 206 is added to the holding force, this centrifugal force is taken into consideration. In the rotation start-up state, a holding force equal to or greater than an inertial force for stopping the wafer 205 is required. In the steady rotating state, a holding force equal to or greater than a centrifugal force calculated by integrating an eccentricity amount, a mass, and a rotation speed of the wafer 205 is required. The holding force against these forces is adjusted by a shape and a mass of the components, such as the bearing 213, the holding component 214 thereof, the rod 216, and the link 218.

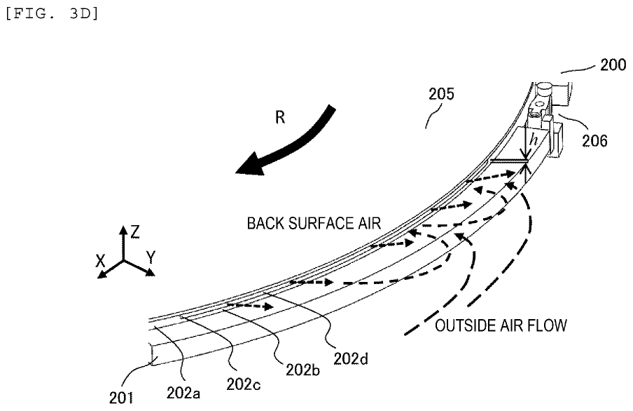

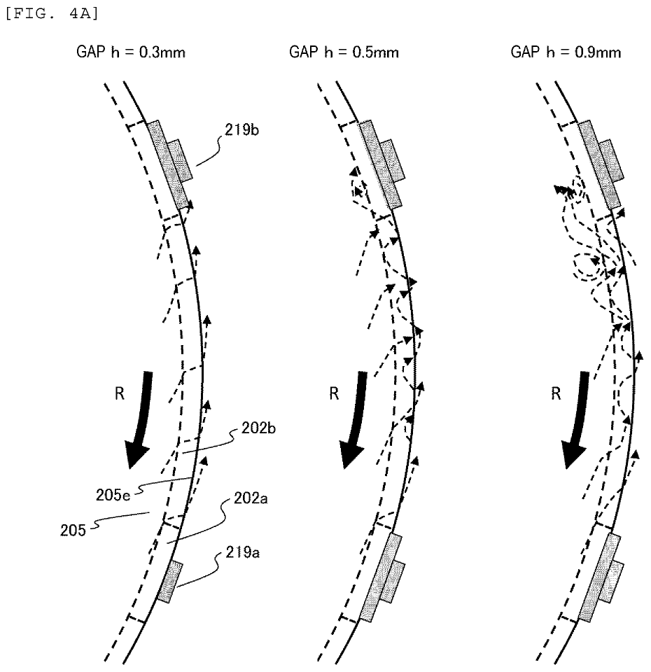

A structure of the turntable on which the wafer 205 is mounted, which is a feature of the present embodiment, will now be described with reference to FIGS. 3A to 3C.

FIG. 3A is a diagram illustrating a turntable according to the present invention on which a wafer is mounted, as observed from a +Z direction.

As illustrated in FIG. 3A, the wafer 205 is supported in the XY direction by the holding claw 219, and as illustrated in FIG. 3B, is supported in the Z direction by the wafer support unit 202 of the outer peripheral portion of the turntable 200. Since the wafer inspection apparatus 10 is used for inspecting foreign matter on the wafer and increasing and adhering of foreign matter is not allowed during the inspection, a contact region between the wafer 205 and the wafer support unit 202 should be as small as possible. Furthermore, if the contact region between the wafer 205 and the wafer support unit 202 is formed near the holding claw 219, which is a supporting unit in the XY direction, the wafer can be supported in both the XY direction and the Z direction. For this reason, in the wafer support unit 202, a supporting (contact) unit for supporting the wafer 205 in the Z direction is not disposed around over the entire perimeter of the wafer 205, but a plurality of the supporting (contact) units are provided at intervals in the circumferential direction. In other words, the wafer support unit 202 has a shape having regions (contact portions) 202a to support the wafer 205 in the Z direction around respectively the holding claws 219 and non-contact regions (non-contact portions) 202b other than that portion.

FIG. 3B is a diagram illustrating a positional relationship between a wafer outer peripheral portion and a ring-shaped wafer support unit, observed from a surface taken along the line B-B of the turntable in FIG. 2A. In other words, FIG. 3B illustrates a diagram of the wafer 205 and the ring-shaped wafer support unit 202 expanded in the circumferential direction, as observed from the outer peripheral side.

As illustrated in FIG. 3B, the contact portion 202a and the non-contact portion 202b with respect to the wafer 205 form a convex-concave shape having a height difference h in the stepped portion 202c in this visual field. In other words, the contact portion 202a is provided in the wafer support unit 202 as a convex portion in contact with a lower end surface 205b of the wafer 205, and the non-contact portion 202b is provided in the wafer support unit 202 as a concave portion recessed in a concave shape from an upper surface of the convex portion.

The contact portion 202a and the non-contact portion 202b with respect to the wafer 205 are alternately arranged on a circumference (circumferential direction of the turntable 200) so as to face an outer peripheral portion of the back surface (lower surface) of the wafer 205. In this case, the same number of the contact regions 202a and the holding claws 219 are disposed in the circumferential direction of the turntable 200. The link 217, the holding unit 218, and the holding claw 219 are disposed radially outward with respect to the wafer support unit 202. At this time, the holding claw 219 of the clamping mechanism 206 is provided within a range that overlaps a region where the contact portion 202a is provided in the circumferential direction of the turntable 200.

Due to such a shape, the wafer 205 is in contact with the wafer support unit 202 only through the contact portion 202a, thereby the contact region can be reduced. As the wafer 205 is mounted on the wafer support unit 202, contact, sliding, or the like of the wafer 205 occurs with respect to the wafer support unit 202. The wafer support unit 202 is formed with a material, such as resin, softer than the wafer 205 so as not to damage the wafer 205. Therefore, there is a possibility that the wafer support unit 202 is slightly worn out by contact, sliding, or the like of the wafer 205, which becomes a factor of foreign matter to be generated or foreign matter to be adhered to the wafer 205. Moreover, it is also considered that when trace amount of metallic elements or metal-based foreign matter are present in the wafer support unit 202, these metallic elements or metal-based foreign matter may adhere to the front surface and/or back surface of a vicinity of the end or the outer peripheral portion of the wafer through the contact portion between the wafer 205 and the wafer support unit 202, thereby causing metallic contamination. Therefore, by making the ring-shaped wafer support unit 202 into the convex-concave shape formed with the contact portion 202a and the non-contact portion 202b, the contact region can be reduced as only the contact portion 202a, thereby reducing potential for an occurrence of foreign matter or metallic contamination.

A contact range (circumferential direction length) 202a1 of the contact portion 202a with respect to the wafer 205 is determined in consideration of a contact state between the wafer 205 and the ring-shaped wafer support unit 202, for example, a margin of a stress affecting the contact therebetween. At this time, a region (circumferential direction length) 202b1 of the non-contact portion 202b with respect to the wafer 205 is determined uniquely accordingly.

In the present embodiment, the contact range 202al of the contact portion 202a is smaller than the range 202b1 of the non-contact portion 202b. In other words, the contact portion 202a and the non-contact portion 202b are disposed so that the circumferential direction length of the contact portion 202a is shorter than the circumferential direction length of the non-contact portion 202b.

More specifically, the wafer inspection apparatus 10 according to the present embodiment includes the following configuration.

In the wafer inspection apparatus 10 including the turntable 200 including the annular wafer support unit 202 and the clamping mechanism 206 including the holding claw 219 for clamping the wafer 205,
the wafer support unit 202 includes: the contact portion 202a in contact with a lower surface of the wafer 205; and the non-contact portion 202b that is not in contact with the lower surface of the wafer 205.

The contact portion 202a and the non-contact portion 202b are alternately arranged in the circumferential direction of the outer peripheral portion of the turntable 200 so as to face the outer peripheral portion of the lower surface of the wafer 205, and are provided such that the length in the circumferential direction of the contact portion 202a is shorter than the length in the circumferential direction of the non-contact portion 202b.

Consequently, in the present embodiment, the solid contact region between the wafer 205 and the turntable 200, which is a factor in the generating of foreign matter, can be reduced, thereby reducing a possibility of dust generation due to wear.

FIG. 3C is a simplified diagram illustrating a cross-sectional surface taken along the line C-C of FIG. 2A.

This diagram illustrates a vicinity of the non-contact portion 202b of the ring-shaped wafer support unit 202. The outer peripheral portion of the wafer 205 includes the gap portion 202d in the non-contact portion 202b, and a gap h between the wafer 205 and the non-contact portion 202b in this gap portion 202d corresponds to the height difference h in the stepped portion 202c between the contact portion 202a and the non-contact portion 202b.

As previously described with reference to FIG. 2B, the back surface air (illustrated by the dashed line) of the wafer 205 flows through the gap between the turntable base 201 and the wafer 205. This back surface air passes over the annular rib 2011, and then is discharged to the outer periphery through the gap portion 202d at the position of the non-contact portion 202b. The back surface air is supplied with clean air containing no foreign matter and the back surface air flow is directed from the center toward the outer periphery and discharged from the gap portion 202d, thereby reducing adhesion of foreign matter to the back surface of the wafer.

FIG. 3D is a schematic diagram illustrating a behavior of an airflow in a vicinity of the outer periphery of the turntable when the turntable according to the present invention, on which the wafer is mounted, rotates.

The back surface air flowing over the back surface of the wafer 205 is discharged from the gap portion 202d to the outside at the non-contact portion 202b. Since a pressure of the back surface of the wafer is set higher than that of the outside, on the average, the back surface air flows in a direction of being discharged to the outside. However, in the case of 300-mm wafers compatible, the turntable 200 rotates at a high speed of, for example, 2000 to 3000 r/min (r/min: revolutions per minute), and a peripheral speed at the turntable outer peripheral portion at this time also reaches approximately 30 to 50 m/s (120 to 180 km/h).

Since there are mechanical parts and structural parts such as the holding claw 219 on the turntable outer peripheral portion, it is considered that this effect may cause turbulence in the flow at the outer peripheral portion. In this case, as illustrated in FIG. 3D, there is a possibility that the back surface air discharged to the outside may be again drawn back into the back surface of the wafer through the gap portion 202d, or the airflow at the outer peripheral portion may be drawn back into the back surface of the wafer through the gap portion 202d. When the back surface air discharged to the outside and the airflow at the outer peripheral portion are drawn back into the back surface of the wafer, there is a possibility that foreign matter generated from mechanical parts such as the holding claw 219 and/or floating foreign matter on the turntable outer peripheral portion may enter the back surface of the wafer to be adhered to the wafer 205. However, a behavior of the airflow or turbulent flow at the outer peripheral portion of the turntable is complicated, and until now it has been difficult to accurately analyze and understand such a phenomenon.

In order to solve this problem, the present inventors have analyzed airflow near the wafer contact portion and the non-contact portion of the turntable outer peripheral portion to clarify the behavior of the airflow and turbulent flow caused by the gap portion 202d (gap h). The height h of the gap portion 202d herein is greater than 0 mm, for example, within a range from 0.1 mm to 1 mm. In order to accurately analyze the behavior of the airflow passing through such a narrow gap, it necessary to make a thickness of an analysis mesh in the Z direction sufficiently thin, for example, on the order of several tens of μm. A size of the mesh in radial and circumferential directions is also reduced in accordance therewith, and thereby the number of meshes increases. Since airflow velocity also significantly changes from a low velocity near approximately 0 m/s to a high velocity of approximately 50 m/s within merely several millimeters at the outer peripheral portion, it is also necessary to construct a turbulent model capable of following such a velocity change. Moreover, turbulence is an unsteady phenomenon, and a wide calculation region is necessary to avoid divergence in analytical calculations. However, in order to suppress analysis time within, for example, 10 hours for practical purposes, it is also necessary to optimize the calculation region and the analysis mesh in accordance to the calculation region. Conventionally, such calculations were too large in scale and required a supercomputer or the like to conduct highly accurate calculations. Recent improvements in the speed of computers have made it possible to conduct such large-scale calculations with high accuracy in practical computing time, thereby advancing quantitative understanding of such phenomena.

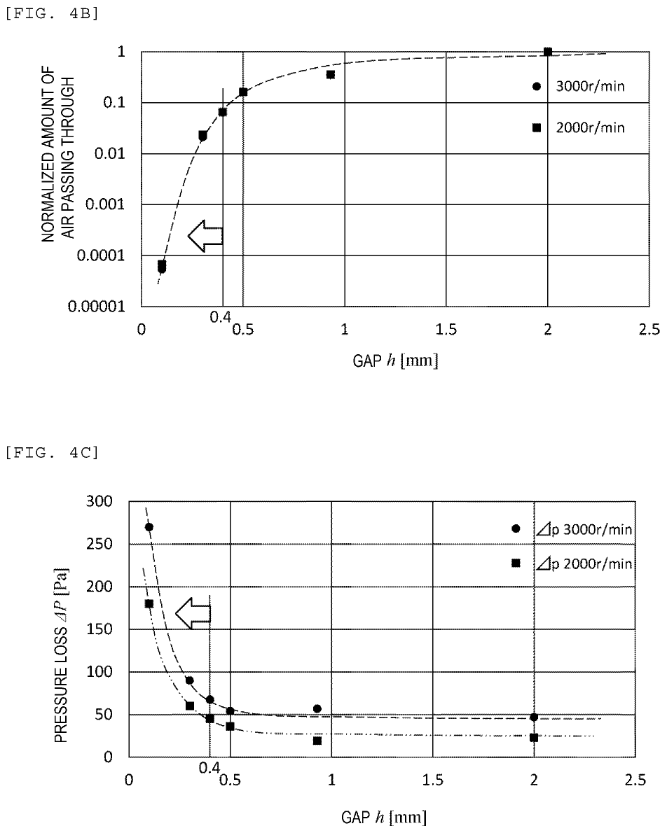

Hereinafter, a behavior of the airflow passing through the gap portion 202d based on an analysis result will be described with reference to FIGS. 4A to 4C.

FIG. 4A is a schematic diagram illustrating a behavior of an airflow in a vicinity of the outer periphery of the turntable when the turntable according to the present invention, on which the wafer is mounted, rotates.

FIG. 4A illustrates an analysis result of an airflow behavior in a vicinity of the outer periphery of the turntable obtained after solving the problems for analysis described above. The outer diameter of the turntable 200 is compatible with a 300-mm wafer, and flow trace lines are schematically illustrated respectively for the gaps h of 0.3 mm, 0.5 mm, and 0.9 mm at a rotation speed of 3000 r/min. In every gap, the back surface air flowing through over the back surface of the wafer 205 is discharged to the outside at the non-contact portion 202b. Needless to say, the back surface air is not discharged from the contact portion 202a near the holding claw 219.

When a gap h is 0.3 mm, the back surface air moves through over the back surface of the wafer to the outer periphery with a velocity component in opposite direction to the rotation direction, changes the direction of the flow trace line when passing through the non-contact portion 202b (corresponds to the gap portion 202d), and is discharged at the wafer edge 205e with a velocity component in the opposite direction to the rotation direction. This behavior of the airflow is the same from a holding claw 219a to a holding claw 219b.

On the other hand, when the gap h is 0.5 mm, the back surface air is discharged at the wafer edge 205e of a vicinity of the holding claw 219a with a velocity component in the opposite direction to the rotation direction. However, as away from the holding claw 219a, a behavior occurs in which the back surface air once discharged from the wafer edge 205e to the outer peripheral side is drawn back into the inner periphery side. This behavior of drawing-back increases as approaching the holding claw 219b.

When the gap h is 0.9 mm, the behavior of drawing back of the back surface air further increases as approaching to the holding claw 219b from the holding claw 219a. Moreover, a vortex is formed in a vicinity of the holding claw 219b, without the back surface air passing through the gap portion 202d. In other words, when the gap h is 0.3 mm, the behavior of the airflow is stable from the holding claw 219a to the holding claw 219b. However, in the case where the gap h is 0.5 mm or 0.9 mm, the behavior is performed as follows: as away from the holding claw 219a and approaching the holding claw 219b, turbulence of the airflow in a vicinity of the outer periphery of the turntable grows, and the back surface air discharged to the outer peripheral side is drawn back into the inner periphery side due to such turbulence of the airflow, or the back surface air does not pass through the gap h and forms a vortex that makes it difficult to be discharged to the outer peripheral side.

In this case, if the distance between the holding claw 219a and the holding claw 219b is reduced, it seems possible to place the holding claw 219b at a position before the turbulence of the airflow in the holding claw 219a grows and it also seems possible to reduce the drawing-back of the back surface air to the side of the inner periphery. However, this increases the number of holding claws 219, i.e., the number of contact regions 202a between the wafer 205 and the ring-shaped support unit 202. As previously described, it is preferable that the number of contact regions 202a should be reduced as possible in order to reduce foreign matter or metallic contamination. The number of contact regions 202a is at least three, for example, preferably six, and at most about nine. FIG. 4A illustrates an example where the number of contact regions 202a is nine (40-degree pitch in the circumferential direction), and it is not preferable to increase the number of holding claws 219 more than this example to reduce the distance between the holding claw 219a and the holding claw 219b.

In accordance with the above description, it is understood that the behavior of the back surface air passing from the outer periphery toward the inner periphery may have a possibility of drawing in foreign matter, etc., and it is necessary to decrease the gap h to reduce such a possibility.

Therefore, the size of the gap h that can reduce the amount of air passing through the gap portion 202d from the outer peripheral side toward the inner periphery side, while having the gap h, was examined using numerical analysis with the amount of air passing through the aforementioned portion as an evaluation parameter. The amount of air passing through is defined as an amount of air per unit time flowing into the back surface of the wafer 205, crossing over the wafer end 205e from the outside, in the gap portion 202d between the wafer 205 and the non-contact portion 202b of the wafer support unit 202. This corresponds to evaluating only an inward flow component with an area-integrated flow rate value.

FIG. 4B is a graphic chart normalizing, when a gap between the wafer and the turntable is changed, an amount of air flowing into the gap from an outside. FIG. 4B illustrates analysis results of the amount of air passing through for the gap h ranging from 0.1 to 2 mm. The amount of air passing through on the vertical axis in FIG. 4B is normalized by setting an inflow amount to 1 when the gap h is 2 mm, and is illustrated on a logarithmic axis.

The rotation speed of the turntable 200 is comparatively examined between 3000 r/min and 2000 r/min, and both amount of air passing through is approximately the same. As the gap h becomes narrower, the amount of air passing through decreases logarithmically. Compared to the amount of air passing through when the gap h is 2.0 mm, it is equal to or less than one-tenth when the gap h is 0.4 mm, and equal to or less than one-fiftieth when the gap h is 0.3 mm. These are effective regions of inhibition against the inflow of air passing across the wafer end 205e at the gap portion 202d from the outer periphery to the inner periphery. In a region further narrower than that, it has characteristics in that the slope of the decrease becomes greater and the amount of air passing through flowing from the outer peripheral side toward the inner periphery side rapidly decreases.

Next, a reason why the amount of air passing through is greatly reduced when the gap h of the gap portion 202d is 0.4 mm or less, or 0.3 mm or less will now be discussed. The pressure loss ΔP in the gap portion 202d denotes a resistance to air passage. Therefore, noting that air cannot pass through the gap when this value is large, the pressure loss is evaluated using the size of the gap h as the representative dimension. The pressure loss ΔP is expressed by Equation 1, and variables for Equation 1 are calculated using Equations 2 and 3.

$$[ Math . 1 ]$$

$$Δ P = ξρ {v}^{2} / 2 \qquad ( Equation 1 )$$

$$[ Math . 2 ]$$

$$\begin{matrix}ξ = 64 / Re , where Re < 2000 or \\ ξ = 0.316 {Re}^{- 0.25} , where Re > 2000\end{matrix} \qquad ( Equation 2 )$$

$$[ Math . 3 ]$$

$$Re = vh / v \qquad ( Equation 3 )$$

Each variable is as follows:
ξ: a pressure loss coefficient,
ρ: a density of air,
v: a peripheral speed of the gap portion,
Re: Reynolds number,
h: the gap in the gap portion 202d, and
υ: a kinematic viscosity coefficient of air.

An analysis result of the pressure loss is illustrated in FIG. 4C. FIG. 4C is a graphic chart of a pressure loss according to, when the gap between the wafer and the turntable is changed, the gap amount.

When the gap h is equal to or less than 0.4 mm, the pressure loss ΔP increases rapidly. This tendency becomes even more remarkable when the gap h is equal to or less than 0.3 mm. Consequently, it can be said that the amount of air flowing into the back surface of the wafer 205 is reduced.

A value of Reynolds number when the gap h is 0.4 mm is approximately 1300 (3000 r/min) to 800 (2000 r/min), and a value of Reynolds number when the gap h is 0.3 mm is approximately 1000 (3000 r/min) to 600 (2000 r/min), and the value of Reynolds number becomes still smaller as the gap h becomes smaller. Generally, in a region where the Reynolds number is low, a flow passing through the gap h becomes a laminar flow, and viscosity becomes dominant.

In FIG. 4A, when the gap h is 0.3 mm and the back surface air passes through the non-contact portion 202b (gap portion 202d), the change in the direction of the flow trace line from the direction opposite to the rotation direction to the radial direction (toward the outer peripheral direction) is considered to be due to a significant effect of viscosity in the gap portion 202d. On the other hand, as the gap h increases to 0.5 mm and then 0.9 mm, the directional change of the flow trace line becomes smaller and has more velocity components in the direction opposite to the rotation direction when passing through the gap portion 202d. This is considered because the effect of viscous in the gap portion 202d is reduced.

Although it is merely a guide, the Reynolds number at which the flow state transitions from a laminar flow to a turbulent flow is generally approximately 2000 to 4000, in the case of flowing in a circle pipe. In FIG. 4A, the transition from the laminar flow to the turbulent flow is observed when the gap h is 0.9 mm, and the value of the Reynolds number at this case is approximately 3000. When the gap h is 0.4 mm, the value of the Reynolds number is approximately 1300, which is a value sufficiently smaller than the Reynolds number at which transition from the laminar flow to the turbulent flow is observed.

Of course, in order to prevent outside air from flowing into the back surface of the wafer 205, it is necessary to form the gap h as in this structure at the outer peripheral portion of the wafer 205. This structure can be formed by providing the height difference h in the stepped portion 202c between the contact portion 202a and the non-contact portion 202b, and by providing the gap portion 202d having the gap h in the ring-shaped wafer support unit 202.

On the basis of the above-described results, in order prevent air from flowing into the back surface of the wafer 205, the gap h between the wafer 205 and the non-contact portion 202b of the wafer support unit 202 should be 0.4 mm or less, more preferably 0.3 mm or less. In other words, in the wafer inspection apparatus 10 of the present embodiment, the gap between the wafer 205 and the wafer support unit 202 in the non-contact portion 202a is set as greater than 0 mm and 0.4 mm or less, and is preferably 0.3 mm or less.

The present inventors actually manufactured prototype turntables with this configuration respectively in which the gaps h of the gap portions 202d are 0.3 mm and 0.9 mm, and experimentally evaluated the adhesion of foreign matter to the back surface of the wafer. In other words, a location where foreign matter is generated is experimentally provided in the wafer conveyance mechanism unit of vicinity of the outer periphery of the turntable to evaluate the foreign matter adhered to the back surface of the wafer when the wafer conveyance is repeated. Consequently, in the case where the gap h is 0.9 mm, adhesion of foreign matter from the location where the foreign matter is generated is observed at the back surface end of the wafer in a vicinity of the location where the foreign matter is generated. In contrast, in the case where the gap h is 0.3 mm, as a result, no adhesion of foreign matter from the location where the foreign matter is generated is not observed. This evaluation is based merely on experimentally providing the location where the foreign matter is generated, and the actual apparatus is set and managed so that no foreign matter is generated. However, this evaluation proves that even when foreign matter is generated from this location due to a certain factor, adhesion of foreign matter to the back surface of the wafer can be reduced by setting the gap h to 0.4 mm or less, more preferably 0.3 mm or less.

In accordance with the above-described structure, it is possible to reduce the contact portion of the wafer to lower the potential of the foreign matter generation or metallic contamination, and it is also possible to reduce the amount of air passing through from the outside to the back surface of the wafer. Therefore, it is possible to actualize a back surface non-contact type wafer inspection apparatus 10 having a high degree of reliability against the foreign matter adhesion and metallic contamination with a lowered factor of foreign matter adhesion to the wafer 205.

### Embodiment 2

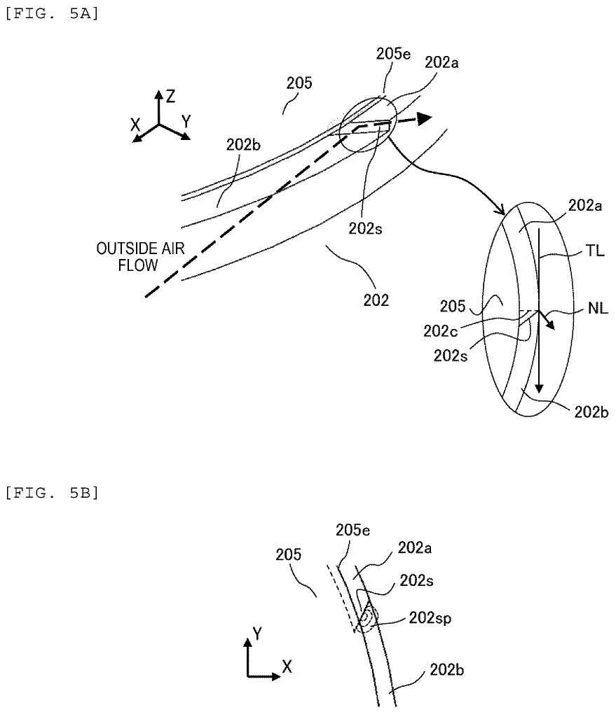

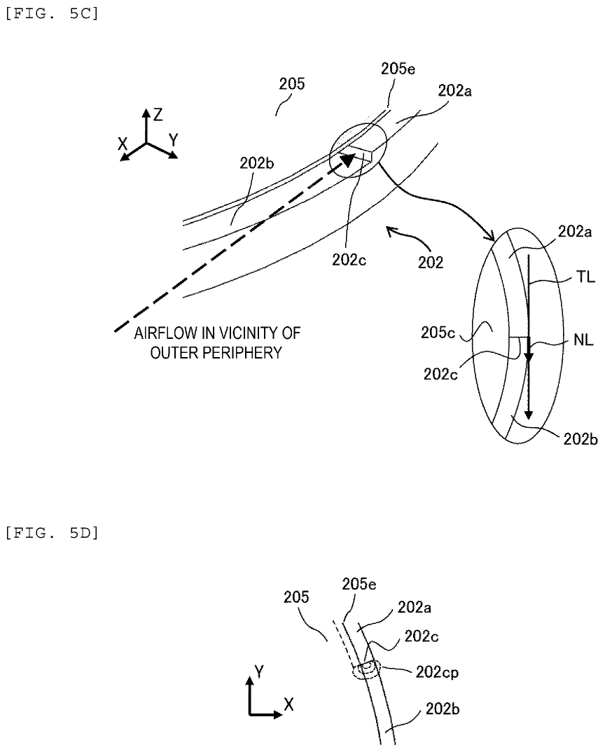

Next, a second embodiment will be described with reference to FIGS. 5A to 5D. FIGS. 5A to 5D are diagrams each illustrating the portion D in FIG. 3A being enlarged.

The feature of the present embodiment is that a normal line of the stepped surface 202c between the contact portion 202a and the non-contact portion 202b with the wafer 205 in the wafer support unit 202 is directed outward from the tangential direction of the outer periphery of the turntable 200.

First, a comparative example with respect to the present embodiment will be described with reference to FIGS. 5C and 5D. FIG. 5C is a diagram according to the comparative example with respect to the second embodiment of the present invention, which is a perspective diagram schematically illustrating, when a normal line of a stepped surface of a wafer support unit is in a tangential direction, a flow line of an airflow in the vicinity of the outer periphery of the turntable which flows toward the stepped surface. FIG. 5D is a diagram according to the comparative example with respect to the second embodiment of the present invention, which is an X-Y plane diagram schematically illustrating, when a normal line of a stepped surface of a wafer support unit is in a tangential direction, pressure distribution generated on the stepped surface.

As illustrated in FIG. 5C, when the stepped portion (stepped surface) 202c between the wafer contact portion 202a and the non-contact portion 202b of the ring-shaped wafer support unit 202 is radiately formed from a center of the turntable 200, the normal line NL of the stepped portion 202c is directed to a direction along (parallel direction to) the tangent TL with respect to the outer periphery of the turntable 200. In this case, since the airflow in a vicinity of the outer periphery of the turntable collides perpendicularly with the stepped portion 202c, a high pressure region is formed on a portion of the stepped portion 202c, and as illustrated in FIG. 5D, pressure distribution, i.e., pressure gradient, 202cp is generated in a periphery of this high pressure region. Moreover, since the stepped portion 202c is formed in the radial direction of the wafer 205 from the inside to the outside of the wafer outer diameter 205e, the pressure gradient 202cp is generated on the region and a rotational upstream side of the stepped surface. In particular, at the rotational upstream portion at the pressure gradient 202cp, the pressure gradient is generated so that the outside air flow is drawn into the back surface of the wafer 205. Consequently, foreign matter flows into the back surface of the wafer, which raises a possibility of increasing factors that cause foreign matter to be adhered to the wafer.

Next, the present embodiment will be described with reference to FIGS. 5A and 5B. FIG. 5A is a diagram according to a second embodiment of the present invention, which is a perspective diagram schematically illustrating, when a normal line of a stepped surface of a wafer support unit faces an outer peripheral side of the turntable, a flow line of an airflow in the vicinity of the outer periphery of the turntable which flows toward the stepped surface. FIG. 5B is a diagram according to the second embodiment of the present invention, which is an X-Y plane diagram schematically illustrating, when the normal line of the stepped surface of the wafer support unit faces the outer peripheral side of the turntable, pressure distribution generated on the stepped surface.

In the present embodiment, the direction of the normal line NL of a stepped portion (stepped surface) 202s is non parallel to the direction of tangent TL of the turntable 200 and is a direction to face outward (radially outward) from the direction of the tangent TL. In other words, the wafer inspection apparatus 10 according to the present embodiment is characterized in that the direction of the normal line NL of the stepped surface 202s between the contact portion 202a and the non-contact portion 202b of the wafer support unit 202 is a direction to face outward with respect to the tangential direction TL of the outer periphery of the turntable 200.

In FIG. 5A, the stepped portion 202s is inclined 45° outwardly with respect to the outer periphery tangential direction of the turntable 200. During the rotation of the turntable 200, the airflow in a vicinity of the outer periphery of the turntable that collides with the stepped portion 202s is guided to the outside of the turntable 200, and a pressure distribution 202sp to be generated is formed approximately in the outside of the wafer 205 as illustrated in FIG. 5B. Consequently, even on upstream of the pressure distribution 202sp, it is possible to reduce the possibility that the airflow at the outer periphery of the turntable enters the back surface of the wafer 205. In addition, the direction of the normal line NL of the stepped portion 202s is preferable to be outside the turntable 200, but it is determined in consideration of a situation of foreign matter generation due to contact since the contact area with the wafer 205 will be increased.

As descried above, in addition to the advantageous effects of the first embodiment, it is possible to actualize a back surface non-contact type wafer inspection apparatus 10 having a high degree of reliability against the foreign matter adhesion and metallic contamination with a lowered factor of foreign matter adhesion to the wafer 205.

In accordance with the above-described embodiments, the solid contact region between the wafer and the turntable, which is a factor in the generating of foreign matter, can be reduced, thereby reducing a possibility of dust generation due to wear. Moreover, the amount of foreign matter adhered to the back surface of the wafer can be reduced since the outside air does not flow into the gap of the back surface of the wafer. Consequently, the wafer inspection apparatus 10 can reduce both the amount of dust generated and the amount of foreign matter adhered. Consequently, a highly reliable wafer inspection apparatus 10 can be obtained.

The present disclosure is not limited to the above-described embodiments, and includes various modifications. For example, the above-described embodiments have been described in detail in order to describe the present invention in an easy-to-understand manner, and are not necessarily limited to examples including all configurations. Further, a part of a certain configuration of an embodiment can be replaced with a configuration of another embodiment, and a certain configuration of an embodiment can be added to a configuration of another embodiment. In addition, for a part of the configuration of each embodiment, another configuration can be added, deleted, or replaced.

### REFERENCE SIGNS LIST

10: Wafer inspection apparatus
11: Wafer insertion unit
12: Wafer conveyance mechanism unit
13: Inspection chamber
131: Optical measurement unit
132: Motor
133: Linear motion moving unit
200: Turntable
201: Turntable base
202: Ring-shaped wafer support unit (ring-shaped support unit)
202a: Contact region between turntable and wafer
202b: Non-contact region between turntable and wafer
202c: Stepped portion between contact region and non-contact region between turntable and wafer (comparative example)
202d: Gap portion in non-contact region between turntable
200 and wafer 205
202s: Slant-shaped stepped portion between contact region and non-contact region between turntable and wafer (embodiment of present invention)
202cp: Pressure distribution during air collision at stepped portion between contact region and non-contact region between turntable and wafer (comparative example)
202sp: Pressure distribution during air collision at slant-shaped stepped portion between contact region and non-contact region between turntable and wafer (embodiment of present invention)
204: Inlet
205: Wafer
205e: Wafer outer diameter
206: Clamping mechanism
211: Cam
212: Air cylinder
213: Bearing
214: Bearing holding unit
215: Compression spring
216: Rod
217: Link
218: Holding unit configured to rotate and hold holding claw
219: Holding claw
2011: Annular rib

1. A wafer inspection apparatus comprising a turntable, the turntable comprising an annular wafer support unit and a clamping mechanism including a holding claw for clamping a wafer,
the wafer support unit comprising a contact portion that is in contact with a lower surface of the wafer, and a non-contact portion that is not in contact with the lower surface of the wafer, wherein
the contact portion and the non-contact portion are alternately arranged in the circumferential direction of the turntable so as to face the outer peripheral portion of the lower surface of the wafer, and are provided such that the length in the circumferential direction of the contact portion is shorter than the length in the circumferential direction of the non-contact portion.

2. The wafer inspection apparatus according to claim 1, characterized in that
a gap between the wafer and the wafer support unit in the non-contact portion is greater than 0 mm and 0.4 mm or less, and preferably 0.3 mm or less.

3. The wafer inspection apparatus according to claim 1, characterized in that
a direction of a normal line of a stepped surface between the contact portion and the non-contact portion of the wafer support unit is a direction to face outward with respect to a tangential direction of an outer periphery of the turntable.

4. The wafer inspection apparatus according to claim 1, characterized in that
the same number of the clamping mechanisms and the contact portions are disposed in the circumferential direction of the turntable.

5. The wafer inspection apparatus according to claim 4, characterized in that
the holding claw of the clamping mechanism is provided within a range that overlaps a region where the contact portion is provided in the circumferential direction of the turntable.

6. The wafer inspection apparatus according to claim 5, characterized in that
the holding claw is disposed radially outward with respect to the wafer support unit.
